(19) United States
(12) Patent Application Publication
(10) Pub. No.: US 2026/0190914 A1
(43) Pub. Date: Jul. 2, 2026

(54) SEALED SHUTTER APPARATUS AND SUBSTRATE PROCESSING APPARATUS INCLUDING THE SAME

(71) Applicant: SEMES CO., LTD., Cheonan-si (KR)

(72) Inventors: In Ki JUNG, Seongnam-si (KR); Se Hoon OH, Cheonan-si (KR); Ho Jong HWANG, Hwaseong-si (KR); Won Sik SON, Hwaseong-si (KR); Jeong Bo SHIM, Suwon-si (KR); Jeong Hyup YU, Hwaseong-si (KR); Do Youn LIM, Hwaseong-si (KR)

(73) Assignee: SEMES CO., LTD., Cheonan-si (KR)

(21) Appl. No.: 19/436,293

(22) Filed: Dec. 30, 2025

(30) Foreign Application Priority Data
Dec. 31, 2024 (KR) 10-2024-0202445

(51) Int. Cl. H10P 72/00; H10P 72/30

(52) U.S. Cl. CPC H10P 72/0441; H10P 72/0408; H10P 72/3406

(57) ABSTRACT

Provided is a sealed shutter device including: a shutter door for opening and closing an opening on a front surface of a chamber; and a shutter driving unit for moving the shutter door to a first position to close the opening, a second position facing the opening but spaced apart from the front surface, and a third position not facing the opening, in which the shutter driving unit includes: a cam follower provided on the shutter door; and a cam guide having a track into which the cam follower is fitted so that the shutter door moves along the first position, the second position, and the third position; and an elastic member for providing elastic force so that the cam follower is in contact with only one predetermined surface of the track.

### CROSS-REFERENCE TO RELATED APPLICATION

This application claims priority to and the benefit of Korean Patent Application No. 10-2024-0202445 filed in the Korean Intellectual Property Office on Dec. 31, 2024, the entire contents of which are incorporated herein by reference.

### TECHNICAL FIELD

The present invention relates to a sealed shutter device, and a substrate processing apparatus including the same.

### BACKGROUND ART

In order to manufacture a semiconductor device, a desired pattern is formed on a substrate through various processes, such as photography, etching, ashing, ion implantation, and thin film deposition. Various treatment liquids and processing gas are used in each process. In addition, in order to remove the treatment liquid used to process the substrate from the substrate, a drying process is performed on the substrate.

In general, the drying process for removing the treatment liquid from the substrate includes a rotary drying process of rotating a substrate at high speed and removing the treatment liquid remaining on the substrate by centrifugal force by the rotation of the substrate, or a supercritical drying process of removing a treatment liquid remaining on the substrate by using a supercritical fluid.

The supercritical drying process loads the substrate into a high-pressure chamber capable of maintaining a high-pressure and high-temperature atmosphere, and then supplies a fluid in a supercritical state onto the substrate to remove the treatment liquid (e.g., organic solvents, and developer solvents) remaining on the substrate.

Toxic gas, such as ozone gas, is used in the supercritical drying process, and sealed shutters are applied to prevent the toxic gas from leaking from the high-pressure chamber.

However, the existing sealed shutter does not have an element that completely determines its position when a cam follower comes into contact with a track, so the rolling of the cam follower is not constant in the high-speed shutter operation, causing abnormal distortion in the cam follower. Furthermore, since the shutter is driven based on the synchronization of two cylinders located on opposite sides of the shutter, a minute time deviation occurs due to the characteristics of the cylinder that is driven at high pressure, and this time deviation acts as a factor that hinders the accurate rolling motion of the cam follower when the cam follower moves along the track.

In addition, synchronous driving of the plurality of cylinders imposes a large load on the cylinder, which may weaken synchronization, and further cause cylinder damage and particles due to shaft wear.

### PRIOR ART LITERATURE

### Patent Document

(Patent Document 1) Korean Patent Application Publication No. 10-2023-0099625 (July 4, 2023)

### SUMMARY OF THE INVENTION

The present invention has been made in an effort to provide a sealed shutter device and a substrate processing apparatus capable of ensuring the operation safety of a cam follower and replacing a plurality of cylinder operations.

The objectives of the present disclosure are not limited thereto and other objectives not stated herein may be clearly understood by those skilled in the art from the following description.

An exemplary embodiment of the present disclosure, a sealed shutter device comprising: a shutter door for opening and closing an opening on a front surface of a chamber; and a shutter driving unit for moving the shutter door to a first position to close the opening, a second position facing the opening but spaced apart from the front surface, and a third position not facing the opening, wherein the shutter driving unit may include: a cam follower provided on the shutter door; and a cam guide having a track into which the cam follower is fitted so that the shutter door moves along the first position, the second position, and the third position; and an elastic member for providing elastic force so that the cam follower is in contact with only one predetermined surface of the track.

According to the exemplary embodiment of the present invention, wherein the shutter driving unit further includes: a cylinder; and a driving plate connected to a rod of the cylinder and provided to be movable in a vertical direction along a guide rail installed in a direction parallel to the cylinder, and the shutter door may be located between the driving plate and the front surface of the chamber.

According to the exemplary embodiment of the present invention, wherein the elastic member may include a coil spring provided between the shutter door and the driving plate.

According to the exemplary embodiment of the present invention, wherein the elastic member may include: a bolt that penetrates the driving plate and is fastened to the shutter door; and a coil spring inserted between a head of the bolt and the driving plate to provide elastic force to the shutter door through the bolt.

According to the exemplary embodiment of the present invention, wherein the coil spring includes a tensile spring that provides tensile force to the shutter door, and the cam follower may be in contact with only one surface of the track by the tensile spring.

According to the exemplary embodiment of the present invention, wherein the coil spring includes a compression spring that provides compression force to the shutter door, and the cam follower may be in contact with only the other surface of the track by the compression spring.

According to the exemplary embodiment of the present invention, wherein the shutter driving unit further may include a spline that is provided between the shutter door and the driving plate, and for horizontal movement of the shutter door.

According to the exemplary embodiment of the present invention, wherein the track may include a vertical movement groove and an inclined movement groove extending from one end of the vertical movement groove.

According to the exemplary embodiment of the present invention, wherein the vertical movement groove corresponds to a vertical movement section in which the shutter door moves from the third position to the second position, and the inclined movement groove may corresponds to an inclined movement section in which the shutter door moves from the second position to the first position.

According to the exemplary embodiment of the present invention, wherein the cam guide and the guide rail are provided at opposite sides of the front surface of the chamber based on the opening, respectively, and the cylinder may be provided at a lower end of a center of the front surface of the chamber based on the opening.

An exemplary embodiment of the present disclosure, a substrate processing apparatus comprising: a treating module for processing a substrate; and a transfer chamber provided with a transfer robot for transferring a substrate to the treating module, wherein the treating module includes: an external chamber having an inner space and having an opening for entry and exit of the substrate on a front surface that is in contact with the transfer chamber; a shutter door for opening and closing the opening; and a shutter driving unit for moving the shutter door to a first position to close the opening, a second position facing the opening but spaced apart from the front surface, and a third position not facing the opening, the shutter driving unit may include: a cam guide having a track into which the cam follower of the shutter door is fitted so that the shutter door moves along the first position, the second position, and the third position; and an elastic member for providing elastic force so that the cam follower is in contact with only one predetermined surface of the track.

According to the exemplary embodiment of the present invention, wherein the shutter driving unit further includes: a cylinder; a driving plate connected to a rod of the cylinder and provided to be movable in a vertical direction along a guide rail installed in a direction parallel to the cylinder, and a spline that is provided between the shutter door and the driving plate, and for horizontal movement of the shutter door, and the shutter door may be located between the driving plate and the front surface of the external chamber.

According to the exemplary embodiment of the present invention, wherein the elastic member may include: a bolt that penetrates the driving plate and is fastened to the shutter door; and a coil spring inserted between a head of the bolt and the driving plate to provide elastic force to the shutter door through the bolt.

According to the exemplary embodiment of the present invention, wherein the elastic member includes a tensile spring positioned between the shutter door and the driving plate and providing tensile force to the shutter door, and the cam follower may be in contact with only one surface of the track by the tensile spring.

According to the exemplary embodiment of the present invention, wherein the elastic member includes a compression spring positioned between the shutter door and the driving plate and providing compression force to the shutter door, and the cam follower may be in contact with only the other surface of the track by the compression spring.

According to the exemplary embodiment of the present invention, wherein the track may include a vertical movement groove and an inclined movement groove extending from one end of the vertical movement groove.

According to the exemplary embodiment of the present invention, wherein the vertical movement groove corresponds to a vertical movement section in which the shutter door moves from the third position to the second position, and the inclined movement groove may corresponds to an inclined movement section in which the shutter door moves from the second position to the first position.

According to the exemplary embodiment of the present invention, wherein a substrate drying treatment may be performed in the treating module.

An exemplary embodiment of the present disclosure, a sealed shutter device comprising: a shutter door for opening and closing an opening on a front surface of a chamber; and a shutter driving unit for moving the shutter door to a first position to close the opening, a second position facing the opening but spaced apart from the front surface, and a third position not facing the opening, wherein the shutter driving unit includes: a cylinder; a driving plate connected to a rod of the cylinder, provided to be movable in a vertical direction along a guide rail installed in a direction parallel to the cylinder, and supporting the shutter door; a cam guide positioned between the driving plate and a front surface of the chamber, and having a track into which the cam follower of the shutter door is fitted so that the shutter door moves along the first position, the second position, and the third position; a spline that is provided between the shutter door and the driving plate, and for horizontal movement of the shutter door; and an elastic member provided between the shutter door and the driving plate, and providing elastic force so that the cam follower is in contact with only one predetermined surface of the track, and the elastic member includes: a bolt that penetrates the driving plate and is fastened to the shutter door; and a coil spring inserted between a head of the bolt and the driving plate to provide elastic force to the shutter door through the bolt.

According to the exemplary embodiment of the present invention, wherein the track includes a vertical movement groove and an inclined movement groove extending from one end of the vertical movement groove, and the vertical movement groove corresponds to a vertical movement section in which the shutter door moves from the third position to the second position, and the inclined movement groove may corresponds to an inclined movement section in which the shutter door moves from the second position to the first position.

According to the exemplary embodiment of the present invention, the cam follower rolls only along one surface of the track by the elastic force of the elastic member, thereby ensuring driving stability of the shutter door and preventing the cam follower from being worn.

According to the exemplary embodiment of the present invention, the shutter door is opened and closed by one cylinder, thereby fundamentally preventing a problem caused by difference in air permeability.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a side cross-sectional view of the substrate processing apparatus illustrated in FIG. 1.

FIG. 3 is a cross-sectional view schematically illustrating an exemplary embodiment of a liquid treating module of FIG. 1.

FIG. 4 is a diagram schematically illustrating an exemplary embodiment of a drying module of FIG. 1.

FIG. 5 is a cross-sectional view illustrating a body illustrated in FIG. 4.

FIG. 6 is a diagram schematically illustrating an opening and closing operation of a shutter door in the drying module.

FIG. 7 is a perspective view of a main part illustrating a shutter driving unit installed on a front surface of an external chamber.

FIG. 8 is a front view of the external chamber illustrating a state in which an opening is opened.

FIGS. 9 and 10 are diagrams for describing the shutter driving unit.

FIG. 11 is a diagram illustrating a cam guide.

FIG. 12A is a diagram illustrating a state in which the shutter door is located at a third position.

FIG. 12B is a diagram illustrating a state in which the shutter door is located at a second position.

FIG. 12C is a diagram illustrating a state in which the shutter door is located at a first position.

FIG. 13 is a diagram illustrating another example of an elastic member.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

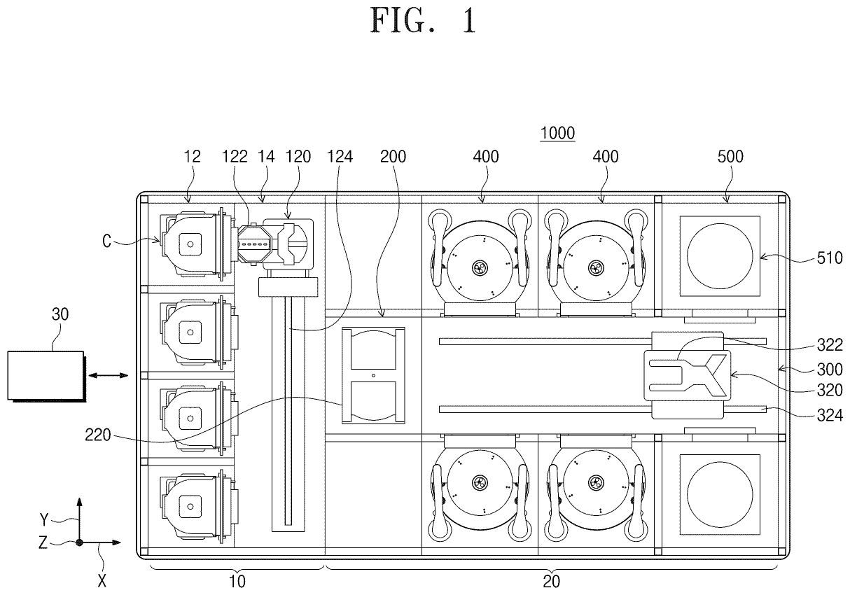

Hereinafter, an exemplary embodiment of the present invention will be described with reference to FIGS. 1 to 13.

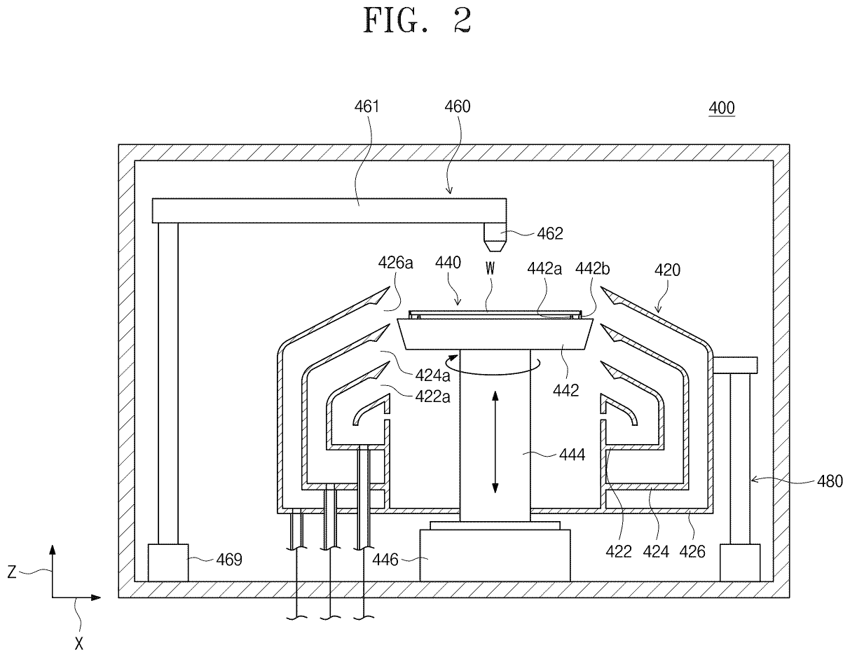

FIG. 1 is a top plan view schematically illustrating a substrate processing apparatus according to an exemplary embodiment of the present invention, and FIG. 2 is a side cross-sectional view of the substrate processing apparatus illustrated in FIG. 1.

Referring to FIGS. 1 and 2, a substrate processing apparatus 1000 includes an index module 10, a treating module 20, and a controller 30.

When viewed from above, the index module 10 and the treating module 20 are disposed along one direction. Hereinafter, the direction in which the index module 10 and the treating module 20 are disposed is referred to as a first direction X, and when viewed from above, a direction perpendicular to the first direction X is referred to as a second direction Y, and a direction perpendicular to both the first direction X and the second direction Y is referred to as a third direction Z.

The index module 10 transfers a substrate W from a container C in which the substrate W is accommodated to the treating module 20, and makes the substrate W, which has been completely processed in the treating module 20, be accommodated in the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates W are accommodated is placed in the load port 12. The plurality of load ports 12 may be provided, and may be disposed in the second direction Y.

As the container C, an airtight container, such as a Front Open Unified Pod (FOUP), may be used. The container C may be placed on the load port 12 by a transfer means (not illustrated), such as an overhead transfer, an overhead conveyor, or an automatic guided vehicle, or an operator.

An index robot 120 is provided to the index frame 14. A guide rail 124 of which a longitudinal direction is the second direction Y is provided within the index frame 14, and the index robot 120 may be provided to be movable on the guide rail 124. The index robot 120 includes a hand 122 on which the substrate W is placed, and the hand 122 may be provided to be movable forward and backward, rotatable about the third direction Z, and movable along the third direction Z. A plurality of hands 122 are provided to be spaced apart in the vertical direction, and the hands 122 may move forward and backward independently of each other.

The controller 30 may control the substrate processing apparatus. The controller 30 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus to perform the substrate processing method described below. For example, the controller 30 may control the fluid supply unit 530 and the fluid discharge unit 550 to perform a substrate processing method described below.

The treating module 20 includes a buffer unit 200, a transfer chamber 300, a liquid treating module 400, and a drying module 500. The buffer unit 200 provides a space in which the substrate W loaded into the treating module 20 and the substrate W unloaded from the treating module 20 stay temporarily. The liquid treating module 400 performs a liquid treatment process of liquid-treating the substrate W by supplying a liquid onto the substrate W. The drying module 500 performs a drying process of removing a liquid remaining on the substrate W. The transfer chamber 300 transfers the substrate W between the buffer unit 200, the liquid treating module 400, and the drying module 500.

The transfer chamber 300 may be provided so that a longitudinal direction is the first direction X. The buffer unit 200 may be disposed between the index module 10 and the transfer chamber 300. The liquid treating module 400 and the drying chamber 500 may be disposed on a side portion of the transfer module 300. The liquid treating module 400 and the transfer chamber 300 may be disposed in the second direction Y. The drying module 500 and the transfer chamber 300 may be disposed in the second direction Y. The buffer unit 200 may be located at one end of the transfer chamber 300.

According to an example, the liquid treating modules 400 may be disposed on opposite sides of the transfer chamber 300, the drying modules 500 may be disposed on opposite sides of the transfer chamber 300, and the liquid treating modules 400 may be disposed closer to the buffer unit 200 than the drying modules 500. However, the present invention is not limited thereto.

At one side and/or the other side of the transfer chamber 300, the liquid treating modules 400 may be provided in an array of A×B (each of A and B is 1 or a natural number larger than 1) in the first direction X and the third direction Z. Further, at one side and/or the other side of the transfer chamber 300, the drying modules 500 may be provided in a number of C×D (C and D are each 1 or a natural number larger than 1) may be provided along each of the first direction X and the third direction Z.

The transfer chamber 300 includes a transfer robot 320. A guide rail 324 having a longitudinal direction in the first direction X is provided in the transfer chamber 300, and the transfer robot 320 may be provided to be movable on the guide rail 324. The transfer robot 320 includes a hand 322 on which the substrate W is placed, and the hand 322 may be provided to be movable forward and backward, rotatable about the third direction Z, and movable along the third direction Z. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction Z. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

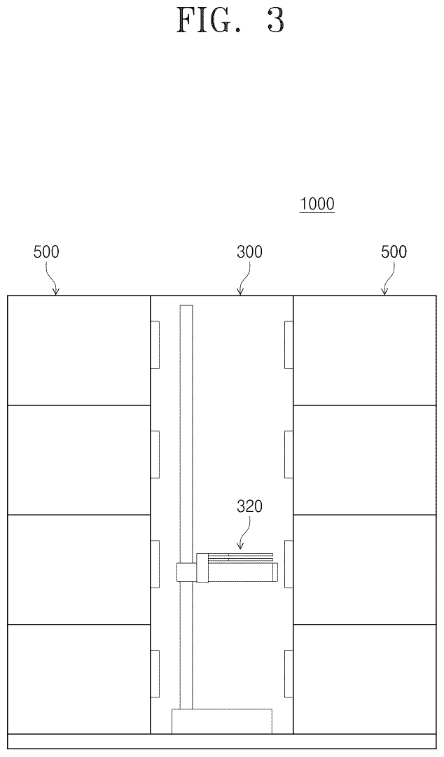

FIG. 3 is a cross-sectional view schematically illustrating an exemplary embodiment of the liquid treating module of FIG. 1.

Referring to FIG. 3, the liquid treating module 400 includes a housing 410, a cup 420, a support unit 440, a liquid supply unit 460, and a lifting unit 480.

The housing 410 may have an inner space in which the substrate W is processed. The housing 410 may have a substantially hexahedral shape. For example, the housing 410 may have a substantially rectangular parallelepiped shape. Further, an opening (not illustrated) through which the substrate W enters and exits is formed in the housing 410. Also, a door (not illustrated) for selectively opening and closing the opening may be installed in the housing 410.

The cup 420 may have a cylindrical shape with an open top. The cup 420 has a treatment space, and the substrate W is liquid-treated in the treatment space. The support unit 440 supports the substrate W in the treatment space. The liquid supply unit 460 supplies the treatment liquid onto the substrate W supported by the support unit 440. The treatment liquid may be provided in a plurality of types, and may be sequentially supplied onto the substrate W. The lifting unit 480 adjusts a relative height between the cup 420 and the support unit 440.

According to an example, the cup 420 includes a plurality of recovery containers 422, 424, and 426. Each of the recovery containers 422, 424, and 426 has a recovery space of recovering the liquid used for the processing of the substrate. Each of the recovery containers 422, 424, and 426 is provided in a ring shape surrounding the support unit 440. As the liquid treatment process proceeds, the treatment liquid scattered by the rotation of the substrate W is introduced into the recovery space through the inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 includes a support plate 442 and a drive shaft 444. An upper surface of the support plate 442 may be provided in a generally circular shape, and may have a diameter larger than a diameter of the substrate W. Further, a support pin 442a supporting the rear surface of the substrate W is provided at the center of the support plate 442, and the upper end of the support pin 442a is provided to protrude from the support plate 442 so that the substrate W is spaced apart from the support plate 442 by a predetermined distance. A chuck pin 442b is provided at an edge portion of the support plate 442. The chuck pin 442b is provided to protrude upward from the support plate 442, and supports the side portion of the substrate W so that the substrate W does not deviate from the support unit 440 when the substrate W is rotated. The drive shaft 444 is driven by a driver 446, is connected to the center of the bottom surface of the substrate W, and rotates the support plate 442 about its central axis.

According to an example, the liquid supply unit 460 may include a nozzle 462. The nozzle 462 may discharge a treatment liquid to the substrate W. The treatment liquid may be a chemical, rinse liquid or an organic solvent. The chemical may be a chemical having strong acid or strong base properties. Further, the rinse liquid may be pure water. The organic solvent may be isopropyl alcohol (IPA). In addition, the treatment liquid supplied by the liquid supply unit 460 may be a developer. For example, the developer supplied by the liquid supply unit 460 may include N-butyl acetate.

In addition, the liquid supply unit 460 may include a plurality of nozzles 462, and the nozzles 462 may supply different types of treatment liquids, respectively. For example, one of the nozzles 462 may discharge a chemical, another one of the nozzles 462 may discharge the rinse liquid, and still another one of the nozzles 462 may discharge the organic solvent. Furthermore, the controller 30 may control the liquid supply unit 460 to supply the organic solvent from still another one of the nozzles 462 to the substrate W after supplying the rinse liquid from another one of the nozzles 462. Accordingly, the rinse liquid supplied onto the substrate W may be substituted with the organic solvent having a small surface tension. In addition, a developer may be supplied from any one of the nozzles 462.

The lifting unit 480 moves the cup 420 in the up and down direction. By the up and down movement of the cup 420, a relative height between the cup 420 and the substrate W is changed. Accordingly, the recovery containers 422, 424, and 426 for recovering the treatment liquid are changed according to the type of liquid supplied to the substrate W, and thus the liquids may be separated and recovered. Unlike the description, the cup 420 may be fixedly installed, and the lifting unit 480 may move the support unit 440 in the vertical direction.

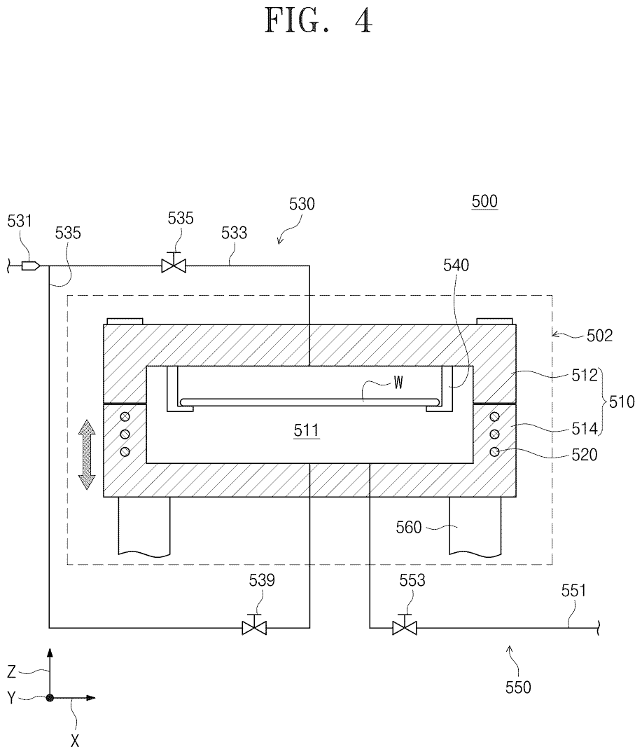

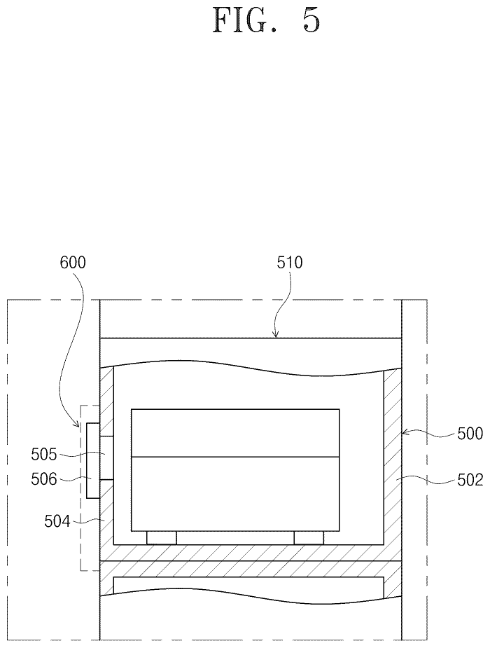

FIG. 4 is a diagram schematically illustrating an exemplary embodiment of the drying module of FIG. 1, and FIG. 5 is a cross-sectional view illustrating a body illustrated in FIG. 4.

Referring to FIGS. 4 and 5, the drying module 500 according to the exemplary embodiment of the present invention may remove a treatment liquid remaining on the substrate W by using a treatment fluid SC in a supercritical state. The treatment liquid to be removed may be any one of the above-described chemical, rinse liquid, organic solvent, and developer. Also, the treatment fluid SC may include carbon dioxide (CO₂). For example, the drying module 500 may remove a developer of N-butyl acetate remaining on the substrate W from the substrate W by using carbon dioxide (CO₂) in a supercritical state.

The drying module 500 may include an external chamber 502, a body 510, a heating member 520, a fluid supply unit 530, a support member 540, a fluid discharge unit 550, and a lifting member 560.

The external chamber 502 provides an inner space. An opening 505 for entering or exiting the substrate is provided in a front surface 504 of the external chamber 502. The front surface 504 of the external chamber 502 is provided to be in contact with the transfer chamber. The opening may be opened or closed by a shutter door 506.

The body 510 may be a high pressure chamber providing a space in which a supercritical drying process is performed. The body 510 may provide a treatment space 511 in which the substrate W is dried by the treatment fluid SC in a supercritical state. The body 510 is made of a material capable of withstanding high pressure equal to or greater than a threshold pressure.

As an example, the body 510 may include an upper body 512 and a lower body 514. The upper body 512 and the lower body 514 may be combined to form the treatment space 511. Any one of the upper body 512 and the lower body 514 may be coupled to the lifting member 560 to move in the vertical direction. For example, the lower body 514 may be coupled to the lifting member 560 to move in the vertical direction by the lifting member 560. Accordingly, the treatment space 511 of the body 510 may be selectively sealed. In the above-described example, the present invention has been described based on the case where the lower body 514 is coupled to the lifting member 560 and moves in the vertical direction as an example, but the present invention is not limited thereto. For example, the upper body 512 may be coupled to the lifting member 560 and move in the vertical direction.

When the lower body 514 is spaced apart from the upper body 512, the treatment space 511 is opened, and in this case, the substrate W is loaded and unloaded. During the process, the lower body 514 is in close contact with the upper body 512 so that the treatment space 511 is sealed from the outside. Here, the substrate W may be loaded in a state in which the organic solvent remains through the organic solvent process in the liquid treating module.

The heating member 520 may heat the treatment fluid SC supplied to the treatment space 511. The heating member 520 may increase the temperature of the treatment space 511 of the body 510. Since the heating member 520 increases the temperature of the treatment space 511, the treatment fluid SC supplied to the treatment space 511 may be converted into a supercritical state or may be maintained in a supercritical state.

Furthermore, the heating member 520 may be buried in the body 510. For example, the heating member 520 may be buried in any one of the upper body 512 and the lower body 514. For example, the heating member 520 may be provided in the lower body 514. However, the present invention is not limited thereto, and the heating member 520 may be provided at various positions capable of increasing the temperature of the treatment space 511. In addition, the heating member 520 may be a heater. However, the present invention is not limited thereto, and the heating member 520 may be variously modified into a known device capable of increasing the temperature of the treatment space 511.

The fluid supply unit 530 may supply the treatment fluid SC to the treatment space 511 of the body 510. The treatment fluid SC supplied by the fluid supply unit 530 may include carbon dioxide (CO₂). The fluid supply unit 530 may include a fluid supply source 531, a first supply line 533, a first supply valve 535, a second supply line 537, and a second supply valve 539.

The fluid supply source 531 may store the treatment fluid SC supplied to the treatment space 511 of the body 510 or may supply the treatment fluid SC to the treatment space 511. The fluid supply source 531 may supply the treatment fluid SC to the treatment space 511 via the first supply line 533 and/or the second supply line 537. Also, the first supply valve 535 may be installed in the first supply line 533. Also, the second supply valve 539 may be installed in the second supply line 537. The first supply valve 535 and the second supply valve 539 may be on/off valves, for example, opening/closing valves. Selectively, the first supply valve 535 and the second supply valve 539 may be flow rate control valves. According to the opening and closing of the first supply valve 535 and the second supply valve 539, the treatment fluid SC may selectively flow through the first supply line 533 or the second supply line 537.

One end of the first supply line 533 may communicate with the treatment space 511. The first supply line 533 may be an upper supply line for supplying the treatment fluid SC, which is drying gas, from an upper portion of the treatment space 511 of the body 510. At least a part of the first supply line 533 may be provided to the upper body 512. Also, the first supply line 533 may be configured such that the supply of the treatment fluid SC faces the upper surface of the substrate W supported by the support member 540. For example, the treatment fluid SC supplied from the first supply line 533 may be supplied to the upper surface of the substrate W. The treatment fluid SC supplied from the first supply line 533 may flow in a direction from top to bottom. For example, the treatment fluid SC supplied from the first supply line 533 may flow in a direction from the upper region of the supported substrate W toward the lower region of the substrate W in the treatment space 511.

One end of the second supply line 537 may communicate with the treatment space 511. The second supply line 537 may be a lower supply line for supplying the treatment fluid SC, which is drying gas, from a lower portion of the treatment space 511 of the body 510. At least a part of the second supply line 537 may be provided to the lower body 514. Also, the second supply line 537 may be configured such that the supply of the treatment fluid SC faces a lower region of the substrate W supported by the support member 540. For example, the treatment fluid SC supplied from the second supply line 537 may flow in a direction from bottom to top. For example, the treatment fluid SC supplied from the second supply line 537 may flow in a direction from the lower region of the substrate W supported by the treatment space 511 toward the upper region of the substrate W.

In the above example, the present invention has been described based on the case where the first supply line 533 and the second supply line 537 are connected to one fluid supply source 531 as an example, but the present invention is not limited thereto. For example, a plurality of fluid supply sources 531 may be provided, the first supply line 533 may be connected to any one of a plurality of fluid supply sources 531, and the second supply line 537 may be connected to another one of the fluid supply sources 531.

In addition, various members, such as a pressure sensor, a temperature sensor, a flow rate control valve, an orifice, and a heater, may be various installed and disposed the first supply line 533, the second supply line 537, or a line between a point where the first supply line 533 and the second supply line 537 are connected and the fluid supply source 531 mentioned in the above example.

The support member 540 may support the substrate W in the treatment space 511. The support member 540 may be configured to support an edge region of the substrate W in the treatment space 511. For example, the support member 540 may be configured to support a lower surface of the edge region of the substrate W in the treatment space 511.

The fluid discharge unit 550 may discharge the treatment fluid SC from the treatment space 511 of the body 510 to the outside. The fluid discharge unit 550 may include a fluid discharge line 551 and a discharge valve 553. One end of the fluid discharge line 551 may communicate with the treatment space 511. At least a portion of the fluid discharge line 551 may be provided to the lower body 514. When the treatment fluid SC is discharged from the treatment space 511, the fluid discharge line 551 may be configured to allow the treatment fluid SC to flow in a direction facing downward from the top of the treatment space 511.

Also, the discharge valve 553 may be installed on the fluid discharge line 551. The discharge valve 553 may be an on/off valve, for example, an opening/closing valve. The discharge valve 553 may also be a flow rate control valve. Members, such as an orifice, a pressure sensor, a temperature sensor, and a pump, may be variously installed and disposed on the fluid discharge line 551.

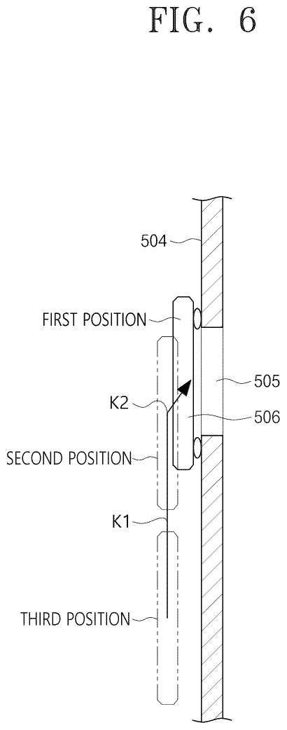

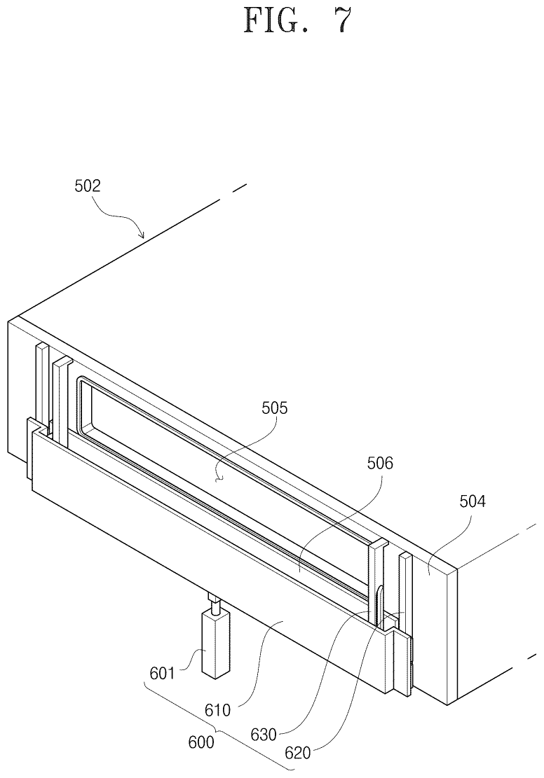

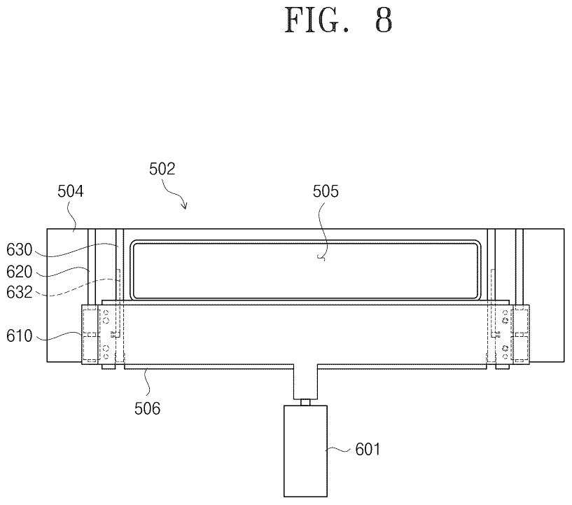

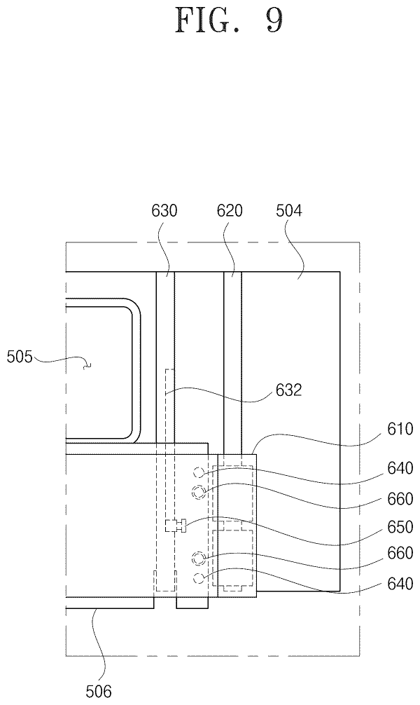

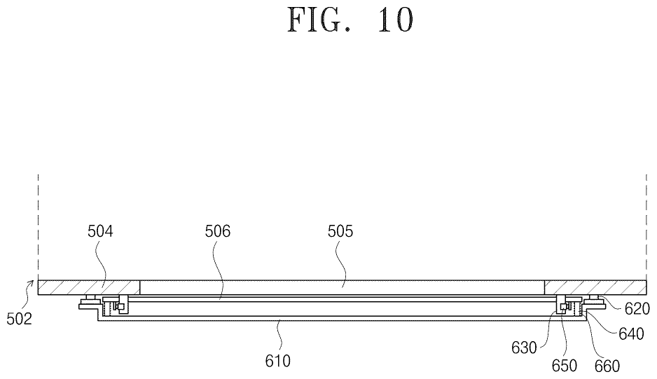

FIG. 6 is a diagram schematically illustrating an opening and closing operation of a shutter door in the drying module, FIG. 7 is a perspective view of a main part illustrating a shutter driving unit installed on a front surface of the external chamber, and FIG. 8 is a front view of the external chamber illustrating a state in which an opening is opened. FIGS. 9 and 10 are diagrams for describing the shutter driving unit.

Referring to FIGS. 6 to 10, the shutter driving unit 600 may be provided to move the shutter door 506 to a first position P1 at which the opening 505 is closed, a second position P2 facing the opening 505 and spaced apart from the front surface 504, and a third position P3 not facing the opening 505. The shutter door 506 may be moved from the third position P3 to the first position P1 via the second position P2 by the shutter driving unit 600 during the closing operation. The movement from the second position to the first position is an oblique direction toward the inside of the external chamber 502. In addition, the shutter door 506 may be moved from the first position P1 to the third position P3 via the second position P2 during the opening operation. That is, the shutter driving unit 600 may move the shutter door 506 from the third position P3 to the first position P1, or from the first position P1 to the third position P3 through the lifting driving of one cylinder 601.

According to an example, the shutter driving unit 600 may include a cylinder 601, a driving plate 610, a guide rail 620, a cam guide 630, a spline 640, a cam follower 650, and an elastic member 660.

The driving plate 610 may be connected to a rod 602 of the cylinder 601 through a connection bracket 573. The driving plate 610 may be provided to be movable in a vertical direction along the guide rail 620 installed in a direction parallel to the cylinder 601. The guide rails 620 may be provided symmetrically on opposite sides of the front surface 504 of the external chamber 502 with respect to the opening 505. The driving plate 610 may be linearly moved in a vertical direction along the guide rail 620 by driving the cylinder 601.

The shutter door 506 may be provided to be moved together with the driving plate 610. The shutter door 506 may be located between the driving plate and the front surface 504 of the external chamber. The cam follower 650 may be provided on the shutter door 506. The cam follower 650 may be fitted into the track 632 of the cam guide 630. The cam guide 630 has a track 632 on which the cam follower 650 is rolled and moved. The shutter door 506 may be moved in a vertical direction together with the driving plate 610, and may be provided to be moved in a horizontal direction from the driving plate 610 in a specific section.

The driving plate 610 and the shutter door 506 may be connected to each other by the spline 640 and the elastic member 660. For example, the spline 640 may include a spline shaft 642 formed in a rod shape and a nut member 644 formed in a cylindrical shape and coupled to the spline shaft 642 through a plurality of balls (not illustrated). The spline shaft 642 is fixedly installed on the driving plate 610, and the nut member 644 is installed on the shutter door 506 to guide horizontal movement of the shutter door 506.

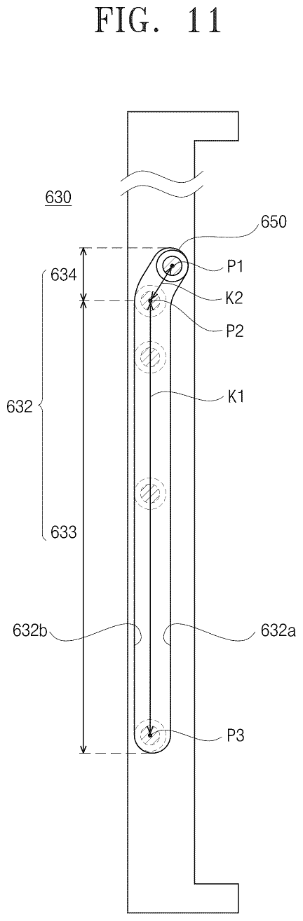

FIG. 11 is a diagram illustrating the cam guide.

Referring to FIGS. 8 to 11, the track 632 of the cam guide 630 may include a vertical movement groove 633 and an inclined movement groove 634 extending from an upper end of the vertical movement groove 633. The inclined movement groove 634 may be provided in an oblique direction. The vertical movement groove 633 may correspond to a vertical movement section K1 in which the shutter door 506 moves from the third position P3 to the second position P2, and the inclined movement groove 634 may correspond to a sealed movement section K2 in which the shutter door 506 moves from the second position P2 to the first position P1. The track 632 includes a first surface 632a close to the opening 505 and a second surface 632b facing the first surface 632a, and the cam follower 650 is moved along any one of the first surface 632a and the second surface 632b. It is most preferable that the elastic member 660 provides elastic force to the shutter door 506 such that the cam follower 650 rolls and moves only along the second surface 632b.

The elastic member 660 provides elastic force so that the cam follower 650 rolls while being in contact with only one predetermined surface of the track 632. The elastic member 660 may be provided between the shutter door 506 and the driving plate 610. The elastic member 660 may be a coil spring. One end of the coil spring 660 may be connected to the shutter door 506, and the other end of the coil spring 660 may be connected to the driving plate 610. As an example, in a case where the coil spring 660 provides force (tensile force) for the shutter door 506 to be pulled outward from the external chamber, the cam follower 650 rolls and moves only along the second surface 632b of the track. Conversely, in a case where the coil spring 660 provides force (compression force) for the shutter door 506 to be pushed inward from the external chamber, the cam follower 650 rolls and moves only along the first surface 632a of the track.

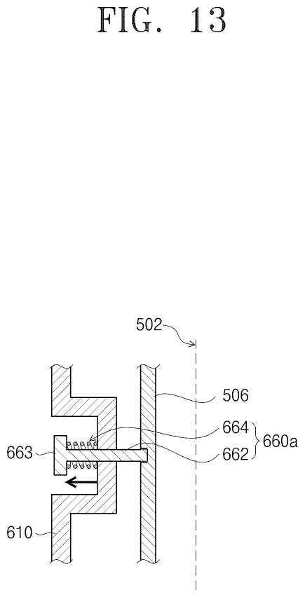

FIG. 13 is a diagram illustrating another example of the elastic member.

As illustrated in FIG. 13, the elastic member 660a may include a bolt 662 and a coil spring 664. The bolt 662 is fastened to the shutter door 506 through a through hole 619 of the driving plate 610. The coil spring 664 is inserted between the head 663 of the bolt 662 and the driving plate 610 to provide elastic force to the shutter door 506 through the bolt 662. That is, elastic force of the coil spring 664 is provided in a direction of an arrow, and the shutter door 506 is elastically supported in an outward direction (arrow) of the external chamber 502.

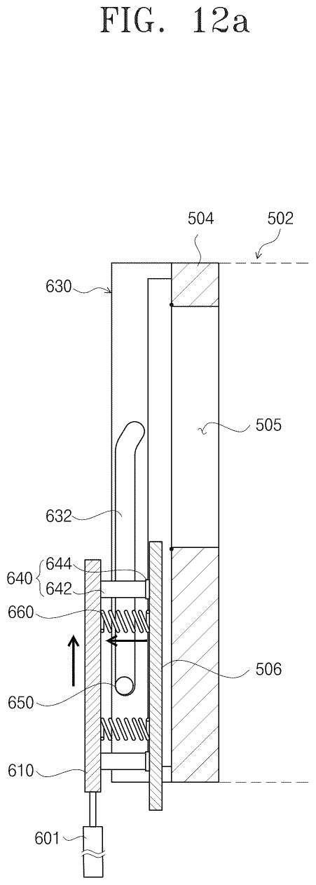

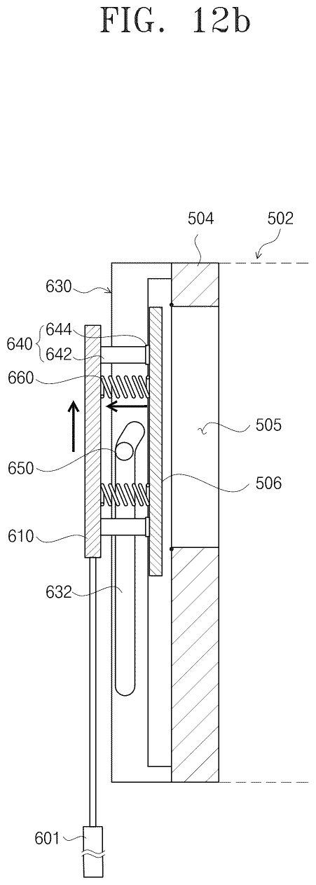

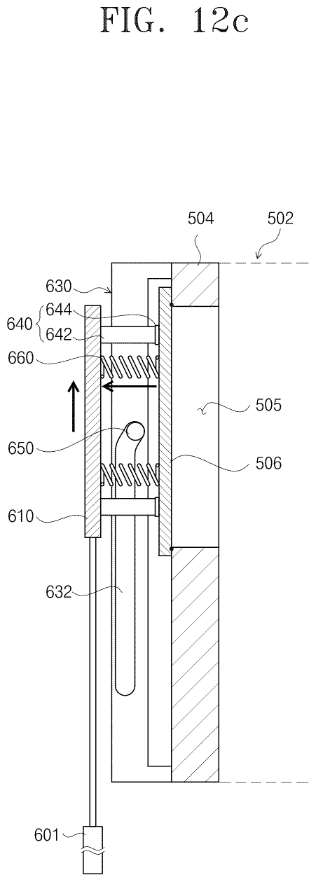

FIG. 12A is a diagram illustrating a state in which the shutter door is located at the third position, FIG. 12B is a diagram illustrating a state in which the shutter door is located at the second position, and FIG. 12C is a diagram illustrating a state in which the shutter door is located at the first position.

In describing the sealing operation of the shutter driving operation with reference to FIGS. 12A to 12C, when the cylinder 601 is operated in an upward direction, the driving plate 610 is moved in an upward direction along the guide rail 620, and the shutter door 506 is moved in the upward direction together with the driving plate 610. In this case, the cam follower 650 positioned at a lower end of the vertical movement groove 633 is moved linearly in the upward direction along the vertical movement groove 633 of the track 632 and moves to an upper end of the vertical movement groove 633. Further, the cam follower 650 is obliquely moved in the inward direction of the external chamber 502 along the inclined movement groove 634. While the shutter door 506 is moved from the third position to the first position, the cam follower 650 is rolled and moved only along the second surface 632b of the track 632 by the elastic member 660. Accordingly, the cam follower 650 may induce a constant rolling movement while the track 632 is moved, thereby securing driving stability of the shutter door 506, and thus preventing the cam follower 650 from being torn. In addition, the shutter door 506 whose movement is completed along the movement trajectory of the cam follower 650 is induced to contact the front surface 504 in the entire section to seal the opening 505.

Although it has been described that the opening and closing structure of the shutter door is applied to the drying module in the present exemplary embodiment, it is not limited to the drying module, and the above-described opening and closing structure of the shutter door may be equally applied to various treating modules that process substrates, such as liquid treating modules.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A sealed shutter device comprising:
a shutter door for opening and closing an opening on a front surface of a chamber; and
a shutter driving unit for moving the shutter door to a first position to close the opening, a second position facing the opening but spaced apart from the front surface, and a third position not facing the opening,
wherein the shutter driving unit includes:
a cam follower provided on the shutter door; and
a cam guide having a track into which the cam follower is fitted so that the shutter door moves along the first position, the second position, and the third position; and
an elastic member for providing elastic force so that the cam follower is in contact with only one predetermined surface of the track.

2. The sealed shutter device of claim 1, wherein the shutter driving unit further includes:
a cylinder; and
a driving plate connected to a rod of the cylinder and provided to be movable in a vertical direction along a guide rail installed in a direction parallel to the cylinder, and
the shutter door is located between the driving plate and the front surface of the chamber.

3. The sealed shutter device of claim 2, wherein the elastic member includes a coil spring provided between the shutter door and the driving plate.

4. The sealed shutter device of claim 2, wherein the elastic member includes:
a bolt that penetrates the driving plate and is fastened to the shutter door; and
a coil spring inserted between a head of the bolt and the driving plate to provide elastic force to the shutter door through the bolt.

5. The sealed shutter device of claim 3, wherein the coil spring includes a tensile spring that provides tensile force to the shutter door, and
the cam follower is in contact with only one surface of the track by the tensile spring.

6. The sealed shutter device of claim 3, wherein the coil spring includes a compression spring that provides compression force to the shutter door, and
the cam follower is in contact with only the other surface of the track by the compression spring.

7. The sealed shutter device of claim 2, wherein the shutter driving unit further includes a spline that is provided between the shutter door and the driving plate, and for horizontal movement of the shutter door.

8. The sealed shutter device of claim 2, wherein the track includes a vertical movement groove and an inclined movement groove extending from one end of the vertical movement groove.

9. The sealed shutter device of claim 8, wherein the vertical movement groove corresponds to a vertical movement section in which the shutter door moves from the third position to the second position, and
the inclined movement groove corresponds to an inclined movement section in which the shutter door moves from the second position to the first position.

10. The sealed shutter device of claim 3, wherein the cam guide and the guide rail are provided at opposite sides of the front surface of the chamber based on the opening, respectively, and
the cylinder is provided at a lower end of a center of the front surface of the chamber based on the opening.

11. A substrate processing apparatus comprising:
a treating module for processing a substrate; and
a transfer chamber provided with a transfer robot for transferring a substrate to the treating module,
wherein the treating module includes:
an external chamber having an inner space and having an opening for entry and exit of the substrate on a front surface that is in contact with the transfer chamber;
a shutter door for opening and closing the opening; and
a shutter driving unit for moving the shutter door to a first position to close the opening, a second position facing the opening but spaced apart from the front surface, and a third position not facing the opening,
the shutter driving unit includes:
a cam guide having a track into which a cam follower of the shutter door is fitted so that the shutter door moves along the first position, the second position, and the third position; and p2 an elastic member for providing elastic force so that the cam follower is in contact with only one predetermined surface of the track.

12. The substrate processing apparatus of claim 11, wherein the shutter driving unit further includes:
a cylinder;
a driving plate connected to a rod of the cylinder and provided to be movable in a vertical direction along a guide rail installed in a direction parallel to the cylinder, and
a spline that is provided between the shutter door and the driving plate, and for horizontal movement of the shutter door, and
the shutter door is located between the driving plate and the front surface of the external chamber.

13. The substrate processing apparatus of claim 12, wherein the elastic member includes:
a bolt that penetrates the driving plate and is fastened to the shutter door; and
a coil spring inserted between a head of the bolt and the driving plate to provide elastic force to the shutter door through the bolt.

14. The substrate processing apparatus of claim 12, wherein the elastic member includes a tensile spring positioned between the shutter door and the driving plate and providing tensile force to the shutter door, and
the cam follower is in contact with only one surface of the track by the tensile spring.

15. The substrate processing apparatus of claim 12, wherein the elastic member includes a compression spring positioned between the shutter door and the driving plate and providing compression force to the shutter door, and
the cam follower is in contact with only the other surface of the track by the compression spring.

16. The substrate processing apparatus of claim 13, wherein the track includes a vertical movement groove and an inclined movement groove extending from one end of the vertical movement groove.

17. The substrate processing apparatus of claim 16, wherein the vertical movement groove corresponds to a vertical movement section in which the shutter door moves from the third position to the second position, and
the inclined movement groove corresponds to an inclined movement section in which the shutter door moves from the second position to the first position.

18. The substrate processing apparatus of claim 13, wherein a substrate drying treatment is performed in the treating module.

19. A sealed shutter device comprising:
a shutter door for opening and closing an opening on a front surface of a chamber; and
a shutter driving unit for moving the shutter door to a first position to close the opening, a second position facing the opening but spaced apart from the front surface, and a third position not facing the opening,
wherein the shutter driving unit includes:
a cylinder;
a driving plate connected to a rod of the cylinder and configured to move in a vertical direction along a guide rail, the shutter door being mounted on the driving plate;
a cam guide positioned between the driving plate and a front surface of the chamber, and having a track into which the cam follower of the shutter door is fitted so that the shutter door moves along the first position, the second position, and the third position;
a spline that is provided between the shutter door and the driving plate, and for horizontal movement of the shutter door; and
an elastic member provided between the shutter door and the driving plate, and providing elastic force so that the cam follower is in contact with only one predetermined surface of the track, and
the elastic member includes:
a bolt that penetrates the driving plate and is fastened to the shutter door; and
a coil spring inserted between a head of the bolt and the driving plate to provide elastic force to the shutter door through the bolt.

20. The sealed shutter device of claim 19, wherein the track includes a vertical movement groove and an inclined movement groove extending from one end of the vertical movement groove, and
the vertical movement groove corresponds to a vertical movement section in which the shutter door moves from the third position to the second position, and the inclined movement groove corresponds to an inclined movement section in which the shutter door moves from the second position to the first position.
